(19) United States
(12) Patent Application Publication
(10) Pub. No.: US 2011/0214735 A1
(43) Pub. Date: Sep. 8, 2011

(54) CONDUCTIVE LAMINATED ASSEMBLY

(75) Inventors: David V. Mahoney, Austin, TX (US); Mitchell T. Huang, Austin, TX (US); Richard D. Twigg, Leander, TX (US)

(73) Assignee: 3M INNOVATIVE PROPERITIES COMPANY, Saint Paul, MN (US)

(21) Appl. No.: 13/125,497

(22) PCT Filed: Nov. 2, 2009
(86) PCT No.: PCT/US2009/062943

§ 371 Date: Apr. 21, 2011

Related U.S. Application Data
(60) Provisional application No. 61/112,258, filed on Nov. 7, 2008.

(51) Int. Cl. H01L 31/0216; B32B 3/10; B32B 3/28; B32B 7/12; B32B 5/16; H01L 31/02; H01L 31/18; B32B 37/12

(52) U.S. Cl. 136/256; 428/138; 428/596; 428/174; 428/354; 428/323; 428/325; 156/332

(57) ABSTRACT

Provided are conductive laminated assemblies and conductive assembly tapes that are used thereon. The conductive laminated assemblies include a conductive foil, a pressure sensitive adhesive, a conductive element as a part of the foil or in the pressure sensitive adhesive and a conductive substrate. The conductive substrate can be a photovoltaic or solar cell.

### TECHNICAL FIELD

Provided are conductive laminated assemblies, such as photovoltaic or solar modules, and conductive assembly tapes that are used thereon.

### BACKGROUND

Conductive foil tapes have been utilized to provide electrical conductivity to substrates such as, for example, electronic devices. Typically these tapes include a conductive metallic foil backing and an adhesive. In some embodiments, the adhesive can be conductive and can incorporate conductive species, such as conductive polymers, or conductive particles. The adhesive can then conduct electricity from the substrate to the foil backing which, in turn, can be connected to other electrical components. In other embodiments, the adhesive can be non-conductive, or insulating but the backing can be embossed so that part of the backing protrudes through the adhesive and can make contact with a conductive substrate when the conductive foil tape is applied to the substrate. In yet other embodiments, the adhesive can be insulating but can contain large conductive particles that can make contact with both the foil backing and the conductive substrate when the tape is applied to the substrate.

For example, U.S. Pat. No. 3,475,213 (Stow) discloses an electrically-conductive adhesive tape which includes pressure sensitive adhesive and electrically-conductive particles distributed as a monolayer in the adhesive. The particles are stated to have a thickness slightly less than the thickness of the adhesive layer. These tapes purportedly exhibit electrical resistances of less than 100 ohms/square inch.

U.S. Pat. No. 4,548,862 (Hartman) is directed to a flexible tape having bridges of electrically conductive particles extending through the adhesive layer. The particles have ferromagnetic cores which can form the requisite bridges by magnetic attraction.

U.S. Pat. Nos. 4,606,962 (Reylek et al.) and 5,300,340 (Calhoun et al.) disclose adhesive layers that contain electrically conductive particles which are preferably spherical and are larger than the thickness of the adhesive between particles. Hard pressure on the adhesive causes the conductive particles to either flatten to the thickness of the adhesive between the particles to provide electrical conductivity between the tape backing and the substrate or the particles are hard and penetrate into the backing and the substrate to form an electrical connection.

U.S. Pat. No. 3,497,383 (Olyphant et al.) discloses an electrically conductive adhesive tape that includes an electrically conductive backing formed by embossing and includes many integral closely spaced projections on one surface and can penetrate through an applied adhesive and make contact with a conductive adhesive.

### SUMMARY

Conductive foil tapes have been shown to be useful as charge collectors on energy-producing conductive laminated assemblies such as solar modules. However, conventional conductive foil tapes can have difficulty achieving high conductivity with the substrate due to high temperature and low pressure processing requirements of solar panels. Additionally, there is a need for conductive foil tapes that can be used to “string” multiple substrates together. This application requires higher current capacity with smaller contact area of the foil tape.

When used on charge collectors for solar panels, the panels and the conductive foil tapes are typically encapsulated in a thermally cured polymer system. The encapsulating process can require vacuum and temperatures of around 155° C. or higher to allow the encapsulant to cure at a reasonable rate. If the adhesive contains residual amounts of unreacted monomer with a boiling point lower than the encapsulating cure temperature, outgassing of the adhesive can occur, bubbles can be produced in the adhesive, and the electrical contact between the foil backing and the substrate can be reduced. Furthermore, if the adhesive has a relatively high stress relaxation rate at the temperature of the encapsulation process then the adhesive can easily shear which can lead to lower electrical conductivity.

What is needed is a conductive foil tape that includes an adhesive that has low stress relaxation (high modulus) at elevated temperatures or fast curing times, low residual monomers that are volatile and outgas at low pressure and elevated temperatures, and, in some embodiments, have conductive metal foils that are embossed with structures that reduce the tape's susceptibility to the expansion of bubbles within the adhesive (whether from outgassing, air entrainment during coating, or air entrainment from lamination) during heated processing of the foil tape on a conductive substrate.

In one aspect, an article is provided that includes a conductive foil having a first major surface, a pressure sensitive adhesive layer in contact with at least a portion of the first major surface of the conductive foil, a conductive element comprising a plurality of protrusions in the conductive foil that extend from the first major surface of the conductive foil into the pressure sensitive adhesive layer, and a conductive substrate in contact with the pressure sensitive adhesive layer, wherein the conductive substrate makes electrical contact with at least a portion of the plurality of protrusions, and wherein the arrangement of the protrusions do not create any substantially enclosed areas.

In another aspect, an article is provided that includes a conductive foil having a first major surface, a pressure sensitive adhesive layer in contact with at least a portion of the first major surface of the conductive foil, a conductive element comprising conductive particles disposed in the pressure sensitive adhesive layer and that are in electrical contact with the first major surface of the conductive foil, and a conductive substrate in contact with the pressure sensitive adhesive layer, wherein the conductive substrate makes electrical contact with at least a portion of the conductive particles, and wherein the pressure sensitive adhesive comprises the reaction product of acrylic monomers having a boiling point of greater than 140° C., and wherein the pressure sensitive adhesive has a stress relaxation modulus of greater than about 3×10⁴ dynes/cm² after 100 seconds measured at 100° C.

In yet another aspect, an article is provided that includes a conductive foil having a first major surface and a second major surface, a first pressure sensitive adhesive layer in contact with at least a portion of the first major surface of the conductive foil, a first conductive element comprising at least one of: (i) a plurality of protrusions in the conductive foil that extend from the first major surface of the conductive foil into the first pressure sensitive adhesive layer or (ii) conductive particles disposed in the first pressure sensitive adhesive layer and that are in electrical contact with the first major surface of the conductive foil, a second pressure sensitive adhesive layer in contact with at least a portion of the second major surface of the conductive foil, a second conductive element comprising at least one of (a) a plurality of protrusions in the conductive foil that extend from the second major surface of the conductive foil into the second pressure sensitive adhesive layer or (b) conductive particles disposed in the second pressure sensitive adhesive layer and that are in electrical contact with the second major surface of the conductive foil, a first conductive substrate in contact with the first pressure sensitive adhesive layer, wherein the first conductive substrate makes electrical contact with at least a portion of the plurality of protrusions extending from the first major surface of the conductive foil into the first pressure sensitive adhesive layer, the conductive particles disposed in the first pressure sensitive adhesive layer, or both, and a second conductive substrate in contact with the second pressure sensitive adhesive layer, wherein the second conductive substrate makes electrical contact with at least a portion of the plurality of protrusions extending from the second major surface of the conductive foil into the second pressure sensitive adhesive layer, the conductive particles disposed in the second pressure sensitive adhesive layer, or both, wherein the arrangement of the plurality of protrusions, if present, does not create any substantially enclosed area, and wherein, if conductive particles are present, the first pressure sensitive adhesive and the second pressure sensitive adhesive each comprise the reaction product of acrylic monomers having a boiling point of greater than 140° C., and wherein the pressure sensitive adhesives each have a stress relaxation modulus of greater than about 3×10⁴ dynes/cm² after 100 seconds measured at 100° C.

In yet another aspect, a method of making an article is provided that includes providing a conductive foil having a first major surface and, optionally, a plurality of protrusions in the conductive foil that extend from the first major surface of the conductive foil; applying a pressure sensitive adhesive layer to the conductive foil wherein the pressure sensitive adhesive, optionally, has conductive particles disposed therein; laminating a conductive substrate to the pressure sensitive adhesive layer to form a laminated assembly; and applying pressure to the laminated assembly so as to provide electrical contact between the conductive foil and the conductive substrate, wherein the arrangement of the plurality of protrusions, if present, to not create any substantially enclosed area, and wherein, if conductive particles are present, the first pressure sensitive adhesive and the second pressure sensitive adhesive each comprise the reaction product of acrylic monomers having a boiling point of greater than 140° C., and wherein the pressure sensitive adhesives each have a stress relaxation modulus of greater than about 3×10⁴ dynes/cm² after 100 seconds measured at 100° C.

In this disclosure:

“array” refers to a regular (repeating) arrangement of features (protrusions), a random arrangement of features, or any arrangement of features;

“frustum” refers to the solid part of a solid shape between two planes, one being the base of the solid and the other a plane cutting through the solid. In this disclosure, the other plane may or may not be parallel to the base;

“(meth)acrylate” or “(meth)acrylic” should be construed to mean both methacrylate and acrylate or both methacrylic and acrylic;

“pattern” or “patterns” refer to a configuration or configurations that can include regular arrays or random arrays of features or structures or a combination of both; and

“substantially enclosed area” refers to an area between raised protrusions that does not allow bubbles in the adhesive to migrate from that area into an adjacent area, for example, these enclosed areas, bounded by an array of protrusions, may have the shape of a rectangle, diamond, parallelogram, circle, oval, ellipse, or any other shape that is bounded, for the most part, on all sides by protrusions and can trap and isolate the air bubble from migration across the protrusions and into an adjacent area.

The provided articles and methods include conductive foil adhesive tapes that can provide conductivity to substrates, such as photovoltaic cells or solar modules either through conductive particles embedded in the adhesive tape, such as silver-coated glass spheres, or through protrusions in the conductive foil backing though the adhesive tape so that the foil backing makes direct contact with the substrate. These conductive tapes can maintain conductivity to the substrates even when subjected to vacuum and high temperature conditions required for encapsulation of these articles. Conductive foil adhesive tapes that can be applied with light force and no heat can enable solar cells to be made thinner and more economical. With improved electrical conductivity these tapes can allow higher currents and lower electrical loss.

The above summary is not intended to describe each disclosed embodiment of every implementation of the present invention. The brief description of the drawing and the detailed description which follows more particularly exemplify illustrative embodiments.

### BRIEF DESCRIPTION OF THE DRAWINGS

FIG. 1 is a cross-sectional illustration of an embodiment having a conductive foil that includes protrusions.

FIG. 2 is a cross-sectional illustration of another embodiment that includes conductive particles on one side of a conductive foil.

FIG. 3 is a cross-sectional illustration of an embodiment having a conductive foil that includes protrusions in two opposite directions.

FIG. 4 is a cross-sectional illustration of another embodiment that includes conductive particles on both sides of a conductive foil.

FIG. 5 is a graph of the stress relaxation of an adhesive used in an embodiment and a comparative adhesive.

FIG. 6 is a photograph of conductive foil that includes protrusions and adhesive and that has been adhered to a glass plate for easy viewing.

### DETAILED DESCRIPTION

In the following description, reference is made to the accompanying set of drawings that form a part of the description hereof and in which are shown by way of illustration several specific embodiments. It is to be understood that other embodiments are contemplated and may be made without departing from the scope or spirit of the present invention. The following detailed description, therefore, is not to be taken in a limiting sense.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein. The use of numerical ranges by endpoints includes all numbers within that range (e.g. 1 to 5 includes 1, 1.5, 2, 2.75, 3, 3.80, 4, and 5) and any range within that range.

Articles are provided that include conductive foil tapes adhered to conductive substrates. The conductive foil tapes can be made from a conductive foil that can be thin and flexible. Typically, the foils are made of copper, aluminum, tin, or other conductive metals. The metal foils can further include a layer of other metals, such as tin, lead, cadmium, or a mixture thereof disposed upon the foil. The foils can have a thickness of less than about 100 μm, less than about 50 μm, or even less than about 25 μm. The conductive foils have two major surfaces. The major surfaces define a plane. The direction normal to the plane of the surfaces is usually referred to as the “z-direction”.

A pressure sensitive adhesive layer is in contact with at least a portion of the first major surface of the conductive foil. The pressure sensitive adhesive is typically an acrylate copolymer and can be crosslinked or uncrosslinked. Crosslinking can be accomplished by adding a chemical crosslinker and heating. Exemplary useful chemical crosslinkers include bisamide crosslinking agents as disclosed in PCT Pat. Publ. No. WO03/099954 (Melancon et al.) or chromium octoate. UV, visible, or electron beam radiation can also be used to crosslink the adhesives. In the case of UV or visible radiation, a radiation absorbing agent (initiator) needs to be added to the adhesive before exposure to radiation. Useful initiators are well known to those of ordinary skill in the art.

Crosslinking can add shear resistance which can be advantageous in maintaining conductivity in the provided articles after the conductive foil tapes are applied to the conductive substrate. To adjust the modulus and coefficient of thermal expansion (CTE) of the adhesive, additives may be added to the adhesive. For example, to increase the adhesive's modulus and decrease its CTE, suitable additives include fumed silica, fused silica, surface-modified silica, and carbon-black microspheres.

The pressure sensitive adhesive should be capable of holding the conductive foil in electrical contact with the conductive substrate during further processing of the provided articles. For example, if the conductive substrate is a solar module, the conductive foil tape can be applied to the solar module so as to provide electrical conductivity between the solar module and the conductive foil. Electrical contact can be facilitated by providing a conductive element in the conductive foil tape. The conductive element can either be a plurality of protrusions in the conductive foil that extend from the first major surface of the conductive foil into the pressure sensitive adhesive layer or can be conductive particles disposed in the pressure sensitive adhesive layer and that are in electrical contact with the first major surface of the conductive foil. When the conductive element is present and the conductive foil tape is applied to the conductive substrate, pressure can be applied to establish electrical conductivity between the conductive foil and the solar module to form a conductive laminated assembly. For solar modules or photovoltaic cells, the conductive laminated assembly can be subjected to encapsulation. Typical encapsulation involves coating the article with an encapsulating polymer such as, for example, ethylene-vinyl acetate and curing it under vacuum (to remove oxygen and facilitate curing) at temperatures of around 155° C. At these temperatures and pressures, volatile residual monomers in the adhesive can outgas, form bubbles and lift the conductive elements from the conductive substrate.

For this reason, it has been found that pressure sensitive adhesives that comprise the reaction product of acrylic monomers having a boiling point of greater than 140° C. can be useful to reduce or to avoid outgassing and delamination caused by the expansion of bubbles either from outgassing or gasses entrained during lamination of the conductive foil tape to the conductive substrate. Useful acrylic monomers include alkyl acrylates such as, for example, 2-ethylhexyl acrylate, isooctyl acrylate, and unsaturated carboxylic acids such as, for example, acrylic acid, and methacrylic acid. Typically useful pressure sensitive adhesives comprise the reaction product of less than about 95 weight percent (wt %) alkyl acrylate, less than about 93 wt % alkyl acrylate, or even less than about 90 wt % alkyl acrylate combined with greater than about 5 wt %, greater than about 7 wt %, or even greater than about 10 wt % unsaturated carboxylic acid. An exemplary pressure sensitive adhesive comprises the reaction product of about 94 wt % 2-ethylhexyl acrylate or isooctylacrylate, or a combination thereof, with about 6 wt % acrylic acid.

It has been found that the rheology of the pressure sensitive adhesive can also play a role in the performance of the adhesive in the provided conductive laminated assemblies. The provided conductive laminated assemblies provide electrical conductivity in the z-direction of the assemblies by forming conductive pathways from the conductive foil to the conductive substrate through a plurality of protrusions in the foil, conductive particles disposed in the adhesive, or both. When the conductive tape with adhesive is laminated to the conductive substrate, conductive pathways are formed which are held together by the adhesive. Delamination of the adhesive from the conductive foil protrusions, conductive particles, or the conductive substrate caused by adhesive movement due to bubbles or relaxation can disturb the electrical contact between the foil and the substrate. It has been found that pressure sensitive adhesives that have a stress relaxation of greater than about 1×10⁴ dynes/cm², greater than about 3×10⁴ dynes/cm2, or even greater than about 5×10⁴ dynes/cm², measured after 100 seconds exposure to 100° C. using an initial strain of 30% are needed to resist delamination—especially when the laminated assembly is exposed to vacuum and temperatures of around 155° C. as, for example, it is exposed to during encapsulation and curing of the encapsulant. The stress relaxation can be measured on any rheometer that operates in a rotational mode.

The provided articles (conductive laminated assemblies) include a conductive element. The conductive element provides an electrical pathway from the conductive foil, through the adhesive, and to the conductive substrate. In one embodiment, the conductive element can be a plurality of protrusions in the conductive foil that extend from the first major surface of the conductive foil into the pressure sensitive adhesive layer. The protrusions can be added onto the conductive foil or can be a part of the conductive foil. Typically the conductive foil is embossed with a pattern that produces protrusions extending in a direction substantially perpendicular to the plane of the first major surface of the foil (the z-direction). The pattern can be in the form of a regular array of protrusions, a random arrangement of protrusions, a combination of different regular or random arrangements of protrusions or any arrangement of protrusions emanating from the foil surface. Furthermore it is contemplated that the protrusions can consist of one, two, three, or more levels of depth. In addition, the phrase “pattern” can refer to a corrugation of the foil that produces raised ridges. The pattern is also not limited by the profile of protrusions in the pattern. They can include any known shape and can, for example, include profiles that of cylinders, cones, parallelepipeds, and prisms. Frustums of these profiles are also within the scope of the shape of the protrusions. The profile of protrusions can have rounded edges, beveled edges, multilevel edges or irregular edges. The protrusions typically extend into and even slightly through the adhesive layer. The adhesive layers can be less than about 200 μm, less than about 100 μm, less than about 50 μm, or even less than about 25 μm. The protrusions can extend in the z-direction less than about 300 μm, less than about 200 μm, less than about 100 μm, or even less than about 50 μm. The protrusions can reduce bubble propagation in subsequent lamination steps if the protrusions are at a low enough density and arrangement so as to allow continuous pathways for bubbles to propagate and for adhesive to migrate so as to fill in the space vacated by a propagating bubble. Typically, the combined areas of the bases of the protrusion is less than about 40%, less than about 20%, less than about 10%, or even less than about 5%, of the total area of the foil. Also, typically the protrusions do not form any substantially enclosed areas that prevent propagation of bubbles or migration of the adhesive to adjacent areas. Exemplary protrusions can be in the shape of a cylinder, the frustum of a cone, or a ridge with a flat top (mesa).

In another embodiment, the conductive element can include conductive particles disposed in the pressure sensitive adhesive layer. Exemplary conductive particles include particles that are typically spherical and are on the order of, or slightly larger than the thickness of the adhesive although other shapes are within the scope of this disclosure. The diameter of the particles can be of the order of the thickness of the adhesive. For example, the diameter of the particles can be greater than about 10 μm, greater than about 25 μm, greater than about 50 μm, greater than about 100 μm, or even greater. The particles can be rigid or can be deformable. The particles can be made of a metal such as, for example, silver, gold, or laminated metals. Laminated metals may have a surface layer that melts and a core that does not melt at the application temperature of the adhesive. Examples of laminated metals include those having a solder surface layer and either a higher melting metal core such as copper, or a nonmetallic core. In another embodiment the conductive particles can have a glass or polymeric core that is coated, at least partially, with a conductive surface coating such as silver. Examples of conductive particles include those disclosed in U.S. Pat. Nos. 4,606,962 (Reylek et al.) and 5,300,340 (Calhoun et al.). The conductive particles are in electrical contact with the first major surface of the conductive foil.

The provided articles include a conductive substrate in contact with the pressure sensitive adhesive and also that makes electrical contact with at least a portion of the plurality of protrusions, the conductive particles, or both. The conductive substrate can be any conductive surface such as, for example, a metal plate, or a plate with a conductive surface. The conductive substrate can also be a transistor, diode, electronic circuit, integrated circuit, a photovoltaic cell or an active solar collector. In some embodiments, the provided article is formed by placing a conductive foil tape (including adhesive and conductive element) on the conductive substrate, applying pressure, heat, or both, to afford electrical contact across the article, and, optionally, encapsulating the article as described above.

In another embodiment, two conductive substrates can be in electrical contact with a conductive foil that has a pressure sensitive adhesive and conductive element on a first major surface and another pressure sensitive adhesive and conductive element on a second major surface. The adhesives and conductive elements on each major surface can be the same or can be different. In this embodiment, electrical contact is made from each of the substrates, through the conductive elements to the conductive foil. In this way, the conductive substrates can be “strung” together physically and electrically.

The provided articles and methods can be further understood by the included drawings. FIG. 1 is a cross-sectional view of an embodiment that includes a conductive foil having protrusions. In laminated conductive assembly 100, conductive foil 102 has been embossed and has protrusions 103 projecting into the article and making physical and electrical contact with conductive substrate 106. Adhesive 104 that was laminated onto conductive foil 102 now is contained in the areas around and between protrusions 103.

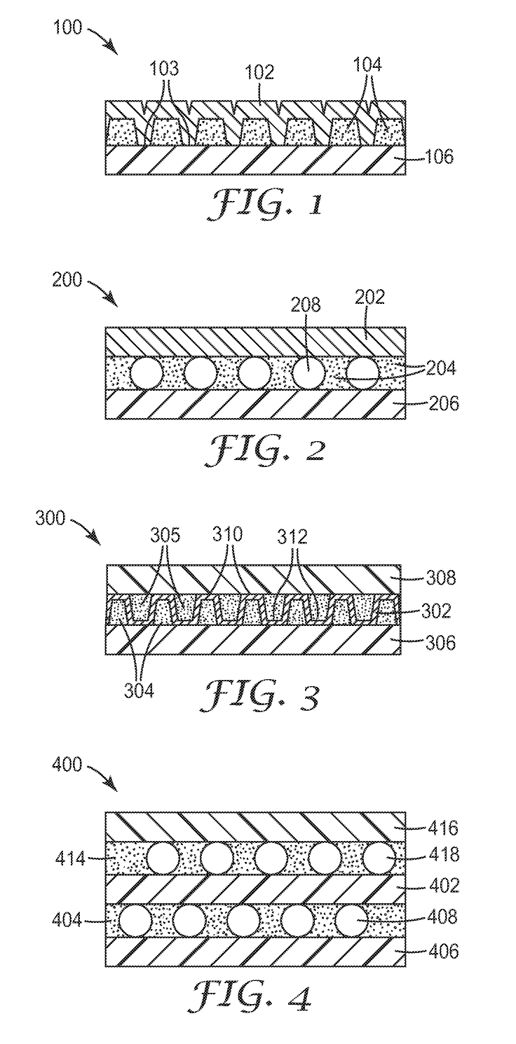

Another embodiment that includes conductive particles in the pressure sensitive adhesive is illustrated in the cross-sectional view shown in FIG. 2. Laminated conductive assembly 200 includes conductive foil 202 (without protrusions or embossing marks). Pressure sensitive adhesive 204 that includes conductive particles 208 has been applied to conductive foil 202. Conductive particles 208 make electrical contact with conductive foil 202 and conductive substrate 206 after lamination.

FIG. 3 is a cross-sectional illustration of an embodiment having a conductive foil that includes protrusions in two opposite directions. Laminated conductive assembly 300 includes conductive foil 302 that has protrusions projecting in two opposite directions from the plane of the foil. The assembly includes a first pressure sensitive adhesive 304 that is in contact with the first major surface of conductive foil 302 and a second pressure sensitive adhesive 305 that is in contact with the second major surface of conductive foil 302. First pressure sensitive adhesive 304 is in contact with first conductive substrate 306 and holds protrusions 312 in the first major surface of conductive foil 302 in electrical contact with substrate 306. Second pressure sensitive adhesive 305 is in contact with second conductive substrate 308 and holds protrusions 310 in the second major surface of conductive foil 302 in electrical contact with substrate 308.

FIG. 4 is a cross-sectional illustration of an embodiment having a conductive foil having two major surfaces. Laminated conductive assembly 400 includes conductive foil 402. The first major surface of conductive foil 402 has a first pressure sensitive adhesive 404 that includes first conductive particles 408 within it. First conductive particles 408 make electrical contact with first conductive substrate 406 and conductive foil 402. The second major surface of conductive foil 402 has a second pressure sensitive adhesive 414 that includes second conductive particles 418 within it. Second conductive particles 418 make electrical contact with second conductive substrate 416 and conductive foil 402.

FIG. 5 is a stress relaxation plot of the adhesive used on 3M 1345 conductive foil tape (available from 3M, St. Paul, Minn.) and 94/6 2-ethylhexyl acrylate/acrylic acid adhesive (94/6 2-EHA/AA—Ex. 1). The adhesive used on 3M 1345 conductive foil tape is a 94/6 isooctylacrylate/acrylamide pressure sensitive adhesive and is used as a comparative example. (Comp. Ex. 1) FIG. 5 shows that the 3M 1345 conductive foil tape adhesive relaxes significantly more than 94/6 2-EHA/AA adhesive over long time periods. The longer relaxation time of the 94/6 2-EHA/AA contributes to its resistance to delamination when used in a laminated conductive assembly.

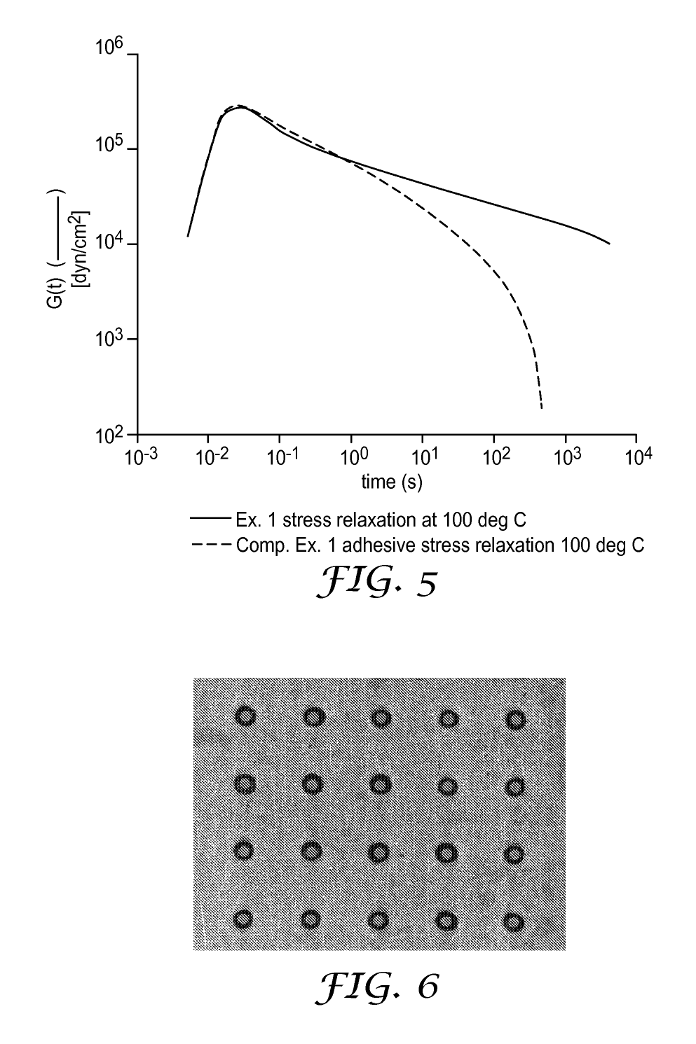

FIG. 6 is a photograph of an embossing pattern that has truncated cones (cone frustums) as patterns. The base of the cones cover about 8.8% of the area of the surface of the conductive foil.

Various modifications and alterations to this invention will become apparent to those skilled in the art without departing from the scope and spirit of this invention. It should be understood that this invention is not intended to be unduly limited by the illustrative embodiments and examples set forth herein and that such examples and embodiments are presented by way of example only with the scope of the invention intended to be limited only by the claims set forth herein as follows.

1. An article comprising:
a conductive foil having a first major surface;
a pressure sensitive adhesive layer in contact with at least a portion of the first major surface of the conductive foil;
a conductive element comprising a plurality of protrusions in the conductive foil that extend from the first major surface of the conductive foil into the pressure sensitive adhesive layer; and
a conductive substrate in contact with the pressure sensitive adhesive layer,
wherein the conductive substrate makes electrical contact with at least a portion of the plurality of protrusions, and
wherein the arrangement of the protrusions does not create any substantially enclosed areas.

2. An article according to claim 1 wherein the conductive foil comprises copper, aluminum, tin, or a combination thereof.

3. An article according to claim 2 wherein the conductive foil further comprises a layer of tin, lead, cadmium, or a mixture thereof, disposed upon the foil.

4. An article according to claim 1 wherein the pressure sensitive adhesive comprises the reaction product of acrylic monomers selected from alkyl acrylates, alkyl methacrylates, acrylic acid, methacrylic acid, and combinations thereof.

5. An article according to claim 4 wherein the pressure sensitive adhesive layer comprises the reaction product of 2-ethylhexyl acrylate, isooctyl acrylate, or a combination thereof, and acrylic acid.

6. An article according to claim 1 wherein the pressure sensitive adhesive consists essentially of the reaction product of 2-ethylhexyl acrylate, isooctyl acrylate, or a combination thereof, and acrylic acid.

7. An article according to claim 1 wherein the pressure sensitive adhesive comprises the reaction product of acrylic monomers having a boiling point of greater than 140° C., and wherein the pressure sensitive adhesive has a stress relaxation modulus of greater than about 3×10⁴ dynes/cm² after 100 seconds measured at 100° C.

8. An article according to claim 1 wherein the plurality of protrusions comprise an array of geometric elements that have a shape selected from the group consisting of ridges, cylinders, cones, parallelepipeds, prisms, corrugations, and frustums thereof.

9. An article according to claim 8 wherein the plurality of protrusions comprise an array of geometric elements that have a shape selected from the group consisting of ridges, cones, and frustums thereof.

10. An article comprising:
a conductive foil having a first major surface;
a pressure sensitive adhesive layer in contact with at least a portion of the first major surface of the conductive foil;
a conductive element comprising conductive particles disposed in the pressure sensitive adhesive layer and that are in electrical contact with the first major surface of the conductive foil; and
a conductive substrate in contact with the pressure sensitive adhesive layer, wherein the conductive substrate makes electrical contact with at least a portion of the conductive particles,
wherein the pressure sensitive adhesive comprises the reaction product of acrylic monomers having a boiling point of greater than 140° C., and wherein the pressure sensitive adhesive has a stress relaxation modulus of greater than about 3×10⁴ dynes/cm² after 100 seconds measured at 100° C.

11. An article according to claim 10 wherein the conductive particles have an average diameter of greater than about 25 μm.

12. An article according to claim 11 wherein the conductive particles comprise silver-coated glass spheres.

13. An article according to claim 1 wherein the conductive substrate comprises an electronic device.

14. An article according to claim 13 wherein the electronic device comprises a photovoltaic cell or a solar panel.

15. An article comprising:
a conductive foil having a first major surface and a second major surface;
a first pressure sensitive adhesive layer in contact with at least a portion of the first major surface of the conductive foil;
a first conductive element comprising at least one of:
(i) a plurality of protrusions in the conductive foil that extend from the first major surface of the conductive foil into the first pressure sensitive adhesive layer; or
(ii) conductive particles disposed in the first pressure sensitive adhesive layer and that are in electrical contact with the first major surface of the conductive foil;
a second pressure sensitive adhesive layer in contact with at least a portion of the second major surface of the conductive foil;
a second conductive element comprising at least one of:
(a) a plurality of protrusions in the conductive foil that extend from the second major surface of the conductive foil into the second pressure sensitive adhesive layer; or
(b) conductive particles disposed in the second pressure sensitive adhesive layer and that are in electrical contact with the second major surface of the conductive foil;
a first conductive substrate in contact with the first pressure sensitive adhesive layer, wherein the first conductive substrate makes electrical contact with at least a portion of the plurality of protrusions extending from the first major surface of the conductive foil into the first pressure sensitive adhesive layer, the conductive particles disposed in the first pressure sensitive adhesive layer, or both; and
a second conductive substrate in contact with the second pressure sensitive adhesive layer,
wherein the second conductive substrate makes electrical contact with at least a portion of the plurality of protrusions extending from the second major surface of the conductive foil into the second pressure sensitive adhesive layer, the conductive particles disposed in the second pressure sensitive adhesive layer, or both,
wherein the arrangement of the plurality of protrusions, if present, does not create any substantially enclosed area, and
wherein, if conductive particles are present, the first pressure sensitive adhesive and the second pressure sensitive adhesive each comprise the reaction product of acrylic monomers having a boiling point of greater than 140° C., and wherein the pressure sensitive adhesives each have a stress relaxation modulus of greater than about 3×10⁴ dynes/cm² after 100 seconds measured at 100° C.

16. An article according to claim 15 wherein the conductive foil comprises copper, aluminum, tin, or a combination thereof.

17. An article according to claim 15 wherein the first pressure sensitive adhesive layer and the second pressure sensitive adhesive layer each comprise the reaction product of acrylic monomers selected from alkyl acrylates, alkyl methacrylates, acrylic acid, methacrylic acid, and combinations thereof.

18. An article according to claim 17 wherein the first pressure sensitive adhesive layer and the second pressure sensitive adhesive layer each comprise the reaction product of 2-ethylhexyl acrylate, isooctyl acrylate, or a combination thereof, and acrylic acid.

19. An article according to claim 15 wherein the first conductive substrate or the second conductive substrate comprises a photovoltaic or a solar module.

20. A method of making an article comprising:
providing a conductive foil having a first major surface and, optionally, a plurality of protrusions in the conductive foil that extend from the first major surface of the conductive foil;
applying a pressure sensitive adhesive layer to the conductive foil wherein the pressure sensitive adhesive, optionally, has conductive particles disposed therein;
laminating a conductive substrate to the pressure sensitive adhesive layer to form a laminated assembly; and
applying pressure to the laminated assembly so as to provide electrical contact between the conductive foil and the conductive substrate,
wherein the arrangement of the plurality of protrusions, if present, does not create any substantially enclosed area, and
wherein, if conductive particles are present, the first pressure sensitive adhesive and the second pressure sensitive adhesive each comprise the reaction product of acrylic monomers having a boiling point of greater than 140° C., and wherein the pressure sensitive adhesives each have a stress relaxation modulus of greater than about 3×10⁴ dynes/cm² after 100 seconds measured at 100° C.

21. The method according to claim 19 wherein the conductive substrate comprises a photovoltaic cell or a solar module.

22. An article according to claim 10 wherein the conductive substrate comprises an electronic device.
